(19) United States
(12) Patent Application Publication
(10) Pub. No.: US 2012/0257780 A1
(43) Pub. Date: Oct. 11, 2012

(54) EARPHONE STRUCTURE WITH NO-SECTION-DIFFERENCE DESIGN AND MANUFACTURING METHOD THEREOF

(75) Inventors: Chung-Yi Huang, Taichung (TW); I-Ming Lin, Taichung (TW); Yu-Lan Liang, Taichung (TW); Chiu-Yun Tung, Taichung (TW)

(73) Assignee: MERRY ELECTRONICS (SHENZHEN) CO., LTD., Shen Zhen (CN)

(21) Appl. No.: 13/082,752

(22) Filed: Apr. 8, 2011

(51) Int. Cl. H04R 1/10; H05K 13/00

(52) U.S. Cl. 381/380; 29/592.1

(57) ABSTRACT

An earphone structure with no-section-difference design is provided, including an earphone casing, a transmission wire and a strain relief thereof. The earphone casing has a joining end to join with a joining section of the transmission wire The strain relief is formed at where the earphone casing and the transmission wire are joined. Along from the earphone casing to the transmission wire, diameter of the strain relief decreases progressively to a same diameter with that of the transmission wire, thereby providing a no-section-difference exterior look thereof between the strain relief and the transmission wire.

### BACKGROUND OF THE INVENTION

1. Field of the Invention

The present invention relates to an earphone structure and manufacturing method thereof, and more particularly to an earphone structure having no section difference between earphone casing and transmission wire on its exterior, and manufacturing method thereof.

2. Brief Description of the Related Art

With reference to FIG. 1, an exterior perspective view of an earphone structure according to prior art, wherein the earphone structure comprises two earphone pieces 10 and each of the two earphone pieces 10 has a strain relief 11 extending from the end thereof respectively, and a transmission wire 12 further extends from each of the strain relief 11 respectively. The two transmission wires 12 converge together and then join to an earphone terminal 13.

The transmission wire 12 is inserted into the earphone casing 10 and electrically connects to a circuit board therein; pulling force too high may cause solder joint damage or loose contact therein. Hence, the strain relief 11 is used for eliminating or reducing the pulling force on the transmission wire 12 in order to maintain stable electrical connection between the transmission wire 12 and the earphone piece 10.

The strain relief 11 fits with the outer edge of a joining part of the transmission wire 12 and the earphone piece 10 after the transmission wire 12 and the earphone piece 10 are electrically connected, wherein the strain relief 11 surrounds and covers part of earphone casing body and part of transmission wire body. When the wire body is twisted and causes the strain relief 11 to deform, unsightly creases will be formed at the joining part: further, a seam may be formed on the joining part under long-term wear and tear, losing the protective feature thereof.

### SUMMARY OF THE INVENTION

In order to overcome the deficiencies of the prior art, an object of the present invention is to provide an earphone structure with no-section-difference design and manufacturing method thereof, and more particularly to an earphone structure having an strain relief, wherein the strain relief covering from an earphone casing to a transmission wire, and there along having a diameter decreasing progressively to a same diameter with that of the transmission wire, thereby providing a no-section-difference exterior thereof.

To achieve the above object, the present invention provides an earphone structure with no-section-difference design, comprising an earphone casing, a transmission wire and a strain relief. The earphone casing comprises a joining end to join with a joining section of the transmission wire. The strain relief is formed at where the earphone casing and the transmission wire are joined. Along from the earphone casing to the transmission wire, a diameter of the strain relief decreases progressively to a same diameter with that of the transmission wire, thereby providing a no-section-difference exterior thereof between the strain relief and the transmission wire.

To achieve the above object, the present invention further provides a manufacturing method for an earphone structure with no-section-difference design; the method comprises steps of: plasticating and forming an earphone casing; joining a transmission wire to an end of the earphone casing; and forming an strain relief at where the earphone casing and the transmission wire are joined, wherein the strain relief is made of a silicone material, and along from the earphone casing to the transmission wire, a diameter of the strain relief decreases progressively to a same diameter with that of the transmission wire.

As the foregoing, the present invention provides an earphone structure with no-section-difference design that is, in contrast to the prior art, capable of providing a smooth curved line exterior look and solving problems of prior art, such as strain relief deformation and creases formed at the section difference edge thereof, caused by long term twisting and winding of the transmission wire.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exterior perspective view of an earphone structure according to prior art;

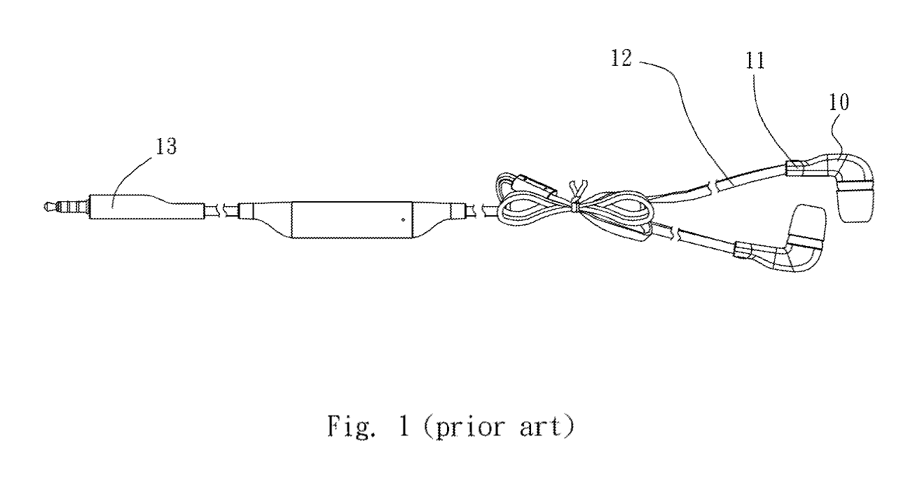

FIG. 2 is an exterior perspective view of an earphone structure with no-section-difference design according to a preferred embodiment of the present invention;

FIG. 3 is a first drawing of a manufacturing process of the earphone structure with no-section-difference design according to the present invention;

FIG. 4 is a second drawing of the manufacturing process of the earphone structure with no-section-difference design according to the present invention; and

FIG. 5 is a third drawing of the manufacturing process of the earphone structure with no-section-difference design according to the present invention

### DETAILED DESCRIPTION OF THE PREFERRED EMBODIMENTS

Preferred embodiments of the present invention are illustrated in detail below with reference to the accompanying drawings.

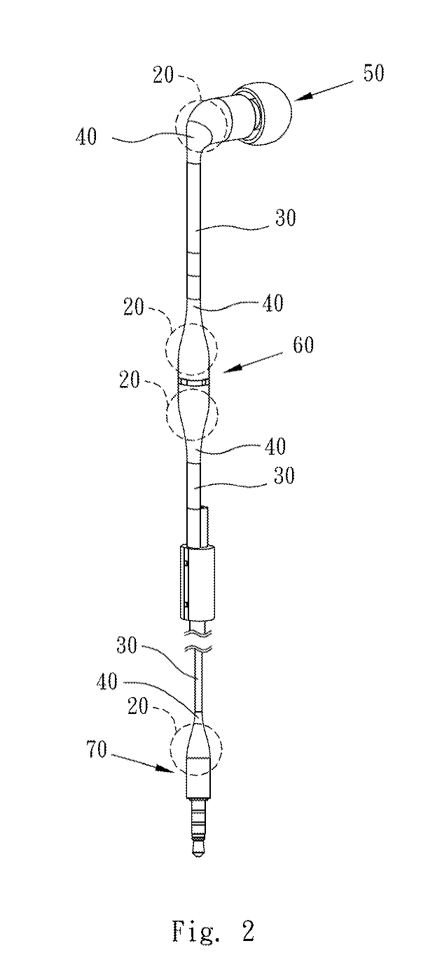

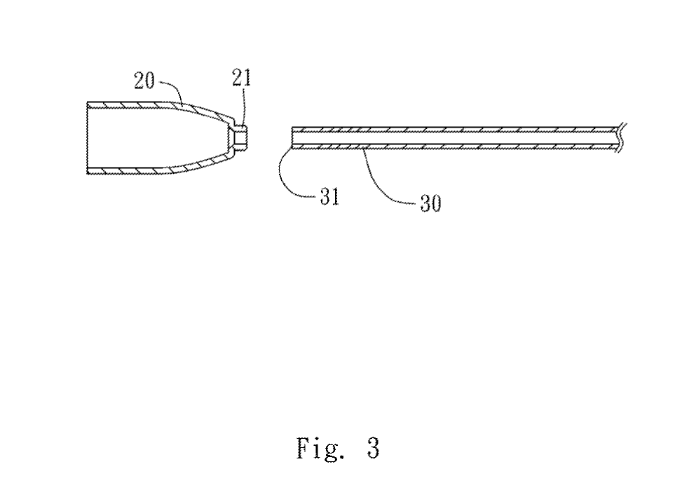

FIG. 2 is an exterior perspective view of an earphone structure with no-section-difference design according to a preferred embodiment of the present invention. With reference to FIG. 2, the earphone structure of the present invention comprises an earphone casing 20, a transmission wire 30 and a strain relief 40. As shown in FIGS. 3 to 5, the earphone casing 20 comprises a joining end 21 to join with a joining section 31 of the transmission wire 30. The strain relief 40 is formed at where the earphone casing 20 and the transmission wire 30 are joined, wherein along from the earphone casing 20 to the transmission wire 30, a diameter of the strain relief 40 decreases progressively to a same diameter with that of the transmission wire 30.

The earphone structure shown in FIG. 2 comprises a sound output section 50, a control section 60 and a connecting section 70, wherein part of the sound output section 50, part of the control section 60 and part of the connecting section 70 are defined as the earphone casing 20, as the dashed line circles marked in FIG. 2, and join with the transmission wire 30. The sound output section 50 comprises components including speaker and driving circuit board therein; the driving circuit board is electrically connected to the transmission wire 30 and is capable of driving the speaker to output a sound to an auditory canal where the sound output section 50 is inserted into. The control section 60 comprises a control circuit board therein, and is used to control volume of audio or select songs; two ends of the control circuit board are electrically connected to the transmission wire 30 respectively, therefore part of the two ends of the control circuit board are regarded as the earphone casing 20 joining with the transmission wire 30. In addition, the connecting section 70 is used for inserting into an electronic device for playing music files such as a MP3 player or a music mobile phone; a plurality of inner terminals is disposed inside the connecting section 70 to electrically connect to the transmission wire 30, and the connecting section 70 is inserted into the electronic device by external terminal. Therefore, the part of the connecting section 70 that covers the inner terminals is regarded as the earphone sing 20 joining with the transmission wire 30.

FIGS. 3 to 5 are drawings of manufacturing process of the earphone structure with no-section-difference design according to the present invention. Wherein, the manufacturing method for the earphone structure of the present invention comprises steps plasticating and forming an earphone casing 20; joining a transmission wire 30 to an end of the earphone casing 20; and forming a strain relief 40 at a joining part of the earphone casing 20 and the transmission wire 30 to cover the joining part, wherein the strain relief 40 is made of a silicone material, and along from the earphone casing 20 to the transmission wire 30, a diameter of the strain relief 40 decreases progressively to a same diameter with that of the transmission wire 30.

Please refer to FIG. 3, wherein the earphone casing 20 is not jointed with the transmission wire 30 yet after plastic formation. The earphone casing 20 thereof may be a part of the sound output section 50, the control section 60 or the connecting section 70. The joining end 21 of the earphone casing 20 is disposed of a thread section. In addition, the transmission wire 30 is made of a silicone material.

It is to be noted that the earphone casing 20 may be made of a plastic material or a metal material.

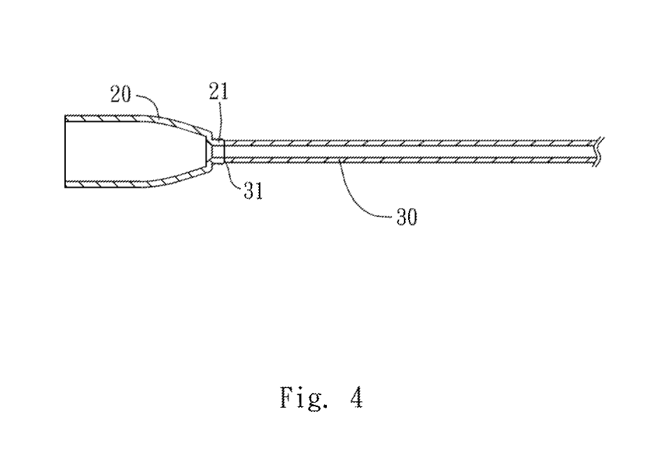

Referring to FIG. 4, the earphone casing 20 is joined to the transmission wire 30 by means of gluing them together or fitting the joining section 31 of the transmission wire 30 with the thread section of the earphone casing 20, wherein the thread therein is capable of preventing the transmission wire 30 from detaching from the earphone casing 20.

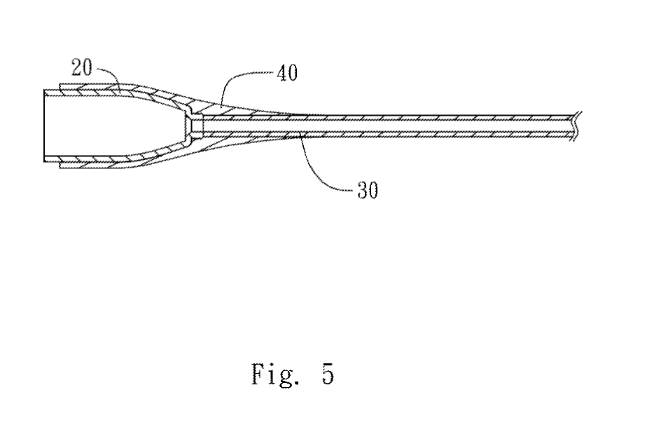

FIG. 5 shows the earphone casing 20 and the transmission wire 30 being joined together and placed in a mould, wherein a silicone material is filled in by thermoforming or injection molding method to form a strain relief 40 that covers where the transmission wire 30 and the earphone casing 20 are joined. Further, as shown in FIG. 5, along from the earphone casing 20 to the transmission wire 30, a diameter of the strain relief 40 decreases progressively to a same diameter with that of the transmission wire 30; this allows a seamless design between the strain relief 40 and the transmission wire 30 and provides a smooth exterior look thereof.

Moreover, the strain relief 40 covers the joining part of the transmission wire 30 and the earphone casing 20 seamlessly by using a silicon material, solving problem of the prior art having seam at the joining part thereof. The strain relief 40 and the transmission wire 30 of the present invention are of a whole form; therefore, when winding and twisting, the strain relief 40 and the transmission wire 30 move and deform with each other, thereby solving the problem of wear and tear at the joining part thereof of the prior art.

Further, the transmission wire 30 according to the foregoing embodiment is a round wire structure; however, the transmission wire 30 may also be a flat wire structure.

As the foregoing, the earphone structure with no-section-difference design according to the present invention provides a smooth curved line exterior look and solves the problems of the prior art such as strain relief deformation and creases formed at the section difference edge thereof. Further, the changes made on the earphone structure and the manufacturing process thereof do not affect the earphone casing protecting the circuit board therein. The strain relief being of soft and elastic material, is capable of preventing the transmission wire from being detached from the circuit board.

While the invention has been described with reference to a preferred embodiment thereof, it is to be understood that modifications or variations may be easily made without departing from the spirit of this invention, which is defined in the appended claims.

What is claimed is:

1. An earphone structure with no-section-difference design, comprising:
an earphone casing having a joining end;
a transmission wire having a joining section to join with the joining end of the earphone casing; and
a strain relief being formed at where the earphone casing and the transmission wire are joined, and along from the earphone casing to the transmission wire, a diameter of the strain, relief decreases progressively to a same diameter with that of the transmission wire.

2. The earphone structure with no-section-difference design as defined in claim 1, wherein the earphone casing is a sound output section of the earphone structure.

3. The earphone structure with no-section-difference design as defined in claim 1, wherein. the earphone casing is a control section of the earphone structure.

4. The earphone structure with no-section-difference design as defined in claim 1, wherein the earphone casing is a connecting section of the earphone structure.

5. The earphone structure with no-section-difference design as defined in claim 1, wherein the earphone casing is made of a plastic material.

6. The earphone structure with no-section-difference design as defined in claim 1, wherein the transmission wire is made of a silicone material.

7. The earphone structure with no-section-difference design as defined in claim 1, wherein the strain relief is made of a silicone material.

8. The earphone structure with no-section-difference design as defined in claim 1, wherein the joining end of the earphone casing is disposed with a thread section; the transmission wire is joined to the earphone casing by fitting the joining section of the transmission wire with the thread section of the joining end of the earphone casing.

9. A manufacturing method for an earphone structure with no-section-difference design, comprising steps of:
providing an earphone casing;
joining a transmission wire to an end of the earphone casing; and
forming a strain relief at where the earphone casing and the transmission wire are joined, wherein the strain relief is made of a silicone material, and along from the earphone casing to the transmission. wire, a diameter of the strain relief decreases progressively to a same diameter with that of the transmission wire.

10. The manufacturing method for the earphone structure with no-section-difference design as defined in claim 9, wherein the transmission wire is made of a silicone material.

11. The manufacturing method for the earphone structure with no-section-difference design as defined in claim 9, wherein the strain relief is being formed by an injection molding method.

12. The manufacturing method for the earphone structure with no-section-difference design as defined in claim 9, wherein the strain relief is being formed by a thermoforming method.

13. The manufacturing method for the earphone structure with no-section-difference design as defined in claim 9, wherein the earphone casing is made of a plastic material or a metal material.
